(19) United States
(12) Patent Application Publication
(10) Pub. No.: US 2026/0253630 A1
(43) Pub. Date: Aug. 27, 2026

(54) MEMORY DEVICES FOR FORMING DATA PATHS

(71) Applicant: SK hynix Inc., Icheon-si Gyeonggi-do (KR)

(72) Inventors: Jun Yeol JEON, Icheon-si Gyeonggi-do (KR); Eun Je KIM, Icheon-si Gyeonggi-do (KR)

(73) Assignee: SK hynix Inc., Icheon-si Gyeonggi-do (KR)

(21) Appl. No.: 19/241,044

(22) Filed: Jun. 17, 2025

(30) Foreign Application Priority Data
Feb. 25, 2025 (KR) 10-2025-0024668

(51) Int. Cl. G11C 11/4074; H01L 25/065; H01L 25/18; H10B 80/00

(52) U.S. Cl. CPC G11C 11/4074; H10B 80/00; H10W 90/00; H10W 90/291; H10W 90/297; H10W 90/722; H10W 90/724

(57) ABSTRACT

A memory device includes a plurality of core dies stacked over a base die. Each of the plurality of core dies includes a first channel region including a first repeater that receives and amplifies first fuse data stored in a fuse data storage circuit during a boot-up operation. Each of the plurality of core dies also includes a second channel region including a second repeater that receives and amplifies second fuse data stored in the fuse data storage circuit during the boot-up operation.

### CROSS-REFERENCE TO RELATED APPLICATIONS

The present application claims priority under 35 U.S.C § 119(a) to Korean Application No. 10-2025-0024668, filed in the Korean Intellectual Property Office on Feb. 25, 2025, the entire contents of which application is incorporated herein by reference.

### BACKGROUND

### 1. Technical Field

The present disclosure relates to memory devices that form data paths.

### 2. Related Art

Stack memory systems, such as high bandwidth memory (HBM) devices, are used in a wide range of applications due to their high bandwidth. Unlike conventional memory systems that use parallel data buses, stack memory systems include a stack memory device including a base die and core dies interconnected by through silicon vias (TSVs). The stack memory device includes a physical interface, such as a physical layer for communication with a processor. The physical layer is designed for high-speed data transmission and efficient communication.

### SUMMARY

In accordance with an embodiment of the present disclosure is a memory device that may include a plurality of core dies stacked over a base die. Each of the plurality of core dies may include a first channel region including a first repeater configured to receive and amplify first fuse data stored in a fuse data storage circuit during a boot-up operation. Each of the plurality of core dies may also include a second channel region including a second repeater configured to receive and amplify second fuse data stored in the fuse data storage circuit during the boot-up operation. The first repeater may be configured to receive first repair data transmitted from the base die through a transmission circuit and amplify the first repair data.

In accordance with an embodiment of the present disclosure is a memory device that may include a plurality of core dies stacked over a base die. Each of the plurality of core dies may include a first channel region including a first repeater configured to receive first fuse data stored in a fuse data storage circuit from a first direction and amplify the first fuse data during a boot-up operation. Each of the plurality of core dies may also include a second channel region including a second repeater configured to receive second fuse data stored in the fuse data storage circuit from the first direction and amplify the second fuse data during the boot-up operation. The first repeater may be configured to receive first repair data transmitted from the base die through a transmission circuit from a second direction and amplify the first repair data. The second repeater may be configured to receive second repair data transmitted from the base die through the transmission circuit from the first direction and amplify the second repair data.

In accordance with an embodiment of the present disclosure is a memory device that may include a plurality of core dies stacked over a base die. Each of the plurality of core dies may include a first selection circuit configured to selectively output one of first fuse data received from a fuse data storage circuit and first repair data received through a transmission circuit, based on a selection signal. Each of the plurality of core dies may also include a second selection circuit configured to selectively output one of second fuse data received from the fuse data storage circuit and second repair data received through the transmission circuit, based on the selection signal. Each of the plurality of core dies may further include a first channel region configured to receive the first fuse data from the first selection circuit during a boot-up operation and receive the first repair data from the first selection circuit for a repair operation. Each of the plurality of core dies may additionally include a second channel region configured to receive the second fuse data from the second selection circuit during the boot-up operation and receive the second repair data from the second selection circuit for the repair operation.

In accordance with an embodiment of the present disclosure is a memory device that may include a plurality of core dies stacked over a base die. Each of the plurality of core dies may include a first channel region, a second channel region, and a transmission circuit positioned in a first direction of the first channel region and positioned in a direction opposite to the first direction of the second channel region. Each of the plurality of core dies may also include a fuse data storage circuit positioned in a second direction of the transmission circuit, wherein the second direction is different from both the first direction and the direction opposite to the first direction. The first channel region may include a first repeater configured to receive and amplify first fuse data stored in the fuse data storage circuit during a boot-up operation. The first repeater may be configured to receive and amplify first repair data transmitted from the base die through the transmission circuit.

In accordance with an embodiment of the present disclosure is a memory device that may include a plurality of core dies stacked over a base die. Each of the plurality of core dies may include a first channel region, a second channel region, and a transmission circuit positioned in a first direction of the first channel region and positioned in a direction opposite to the first direction of the second channel region. Each of the plurality of core dies may also include a fuse data storage circuit positioned in the first direction of the first channel region, the transmission circuit, and the second channel region. The first channel region may include a first repeater configured to receive and amplify first fuse data stored in the fuse data storage circuit during a boot-up operation. The first repeater may be configured to receive and amplify first repair data transmitted from the base die through the transmission circuit.

In accordance with an embodiment of the present disclosure is a memory device that may include a plurality of core dies stacked over a base die. Each of the plurality of core dies may include a first channel region, a second channel region, and a transmission circuit positioned in a first direction of the first channel region and positioned in a direction opposite to the first direction of the second channel region. Each of the plurality of core dies may also include a fuse data storage circuit positioned in a second direction of the transmission circuit. Each of the plurality of core dies may further include a first selection circuit positioned in the second direction of the second channel region, wherein the second direction is different from both the first direction and the direction opposite to the first direction. Each of the plurality of core dies may additionally include a second selection circuit positioned in the second direction of the second channel region. The first selection circuit may be configured to selectively output one of first fuse data received from the fuse data storage circuit and first repair data received through the transmission circuit, based on a selection signal. The first channel region may be configured to receive the first fuse data from the first selection circuit during a boot-up operation and receive the first repair data from the first selection circuit for a repair operation.

### BRIEF DESCRIPTION OF THE DRAWINGS

FIG. 1 illustrates a memory device according to an embodiment of the present disclosure.

FIG. 2 illustrates a core die according to an embodiment of the present disclosure.

FIG. 3 illustrates a repeater according to an embodiment of the present disclosure.

FIG. 4 illustrates a path through which fuse data is transmitted in a core die.

FIG. 5 illustrates a path through which repair data is transmitted in a core die.

FIG. 6 illustrates a core die according to an embodiment of the present disclosure.

FIG. 7 illustrates a path through which fuse data is transmitted in a core die.

FIG. 8 illustrates a path through which repair data is transmitted in a core die.

FIG. 9 illustrates a core die according to an embodiment of the present disclosure.

FIG. 10 illustrates a path through which fuse data is transmitted in a core die.

FIG. 11 illustrates a path through which repair data is transmitted in a core die.

FIG. 12 illustrates a core die according to an embodiment of the present disclosure.

FIG. 13 illustrates a path through which fuse data is transmitted in a core die.

FIG. 14 illustrates a path through which repair data is transmitted in a core die.

FIG. 15 is a block diagram illustrating a memory system according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

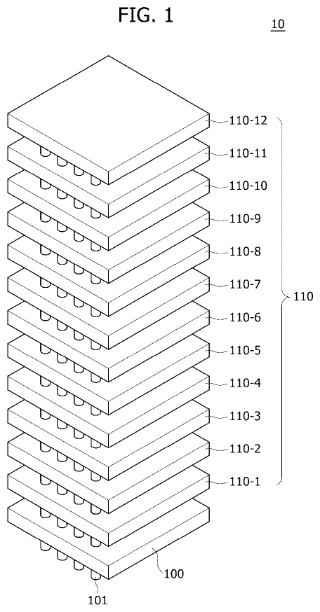

FIG. 1 illustrates a memory device 10 according to an embodiment of the present disclosure.

As shown in FIG. 1, the memory device 10 includes a base die 100 and a plurality of core dies 110.

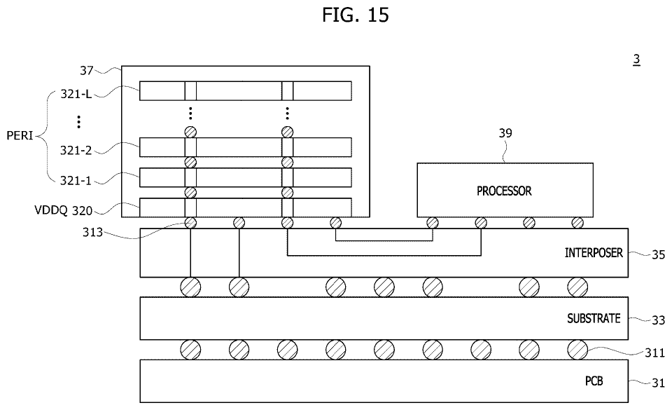

The base die 100 controls an operation of storing data in the core dies 110 and controls an operation of outputting data stored in the core dies 110. The base die 100 includes micro-bump pads 101 and is positioned on an interposer, for example, reference numeral 35 in FIG. 15, or on a substrate, for example, reference numeral 33 in FIG. 15.

The core dies 110 are stacked over the base die 100 with micro-bump pads in between. The base die 100 and the core dies 110 are vertically connected using through-vias. The core dies 110 include twelve core dies 110-1 to 110-12 in this example, but the present disclosure is not limited to this example. The core dies 110 may be implemented in various numbers, such as four, eight, sixteen, twenty, and so forth according to embodiments.

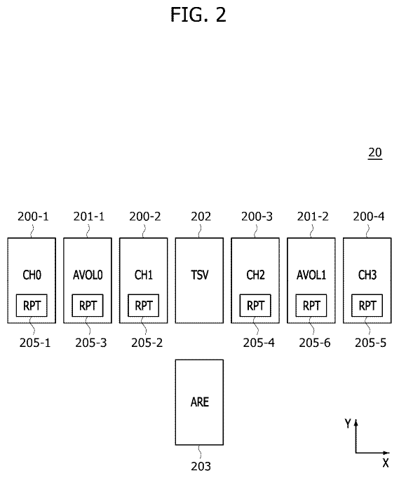

FIG. 2 illustrates a core die 20 according to an embodiment of the present disclosure.

As shown in FIG. 2, the core die 20 includes a first channel region (CH0) 200-1, a first power supply region (AVOL0) 201-1, a second channel region (CH1) 200-2, a third channel region (CH2) 200-3, a second power supply region (AVOL1) 201-2, a fourth channel region (CH3) 200-4, a transmission region (TSV) 202, and a fuse data storage circuit (ARE) 203.

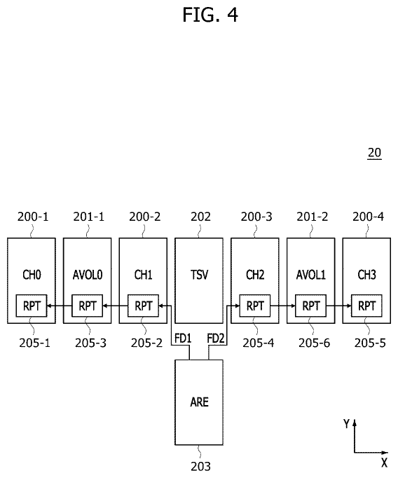

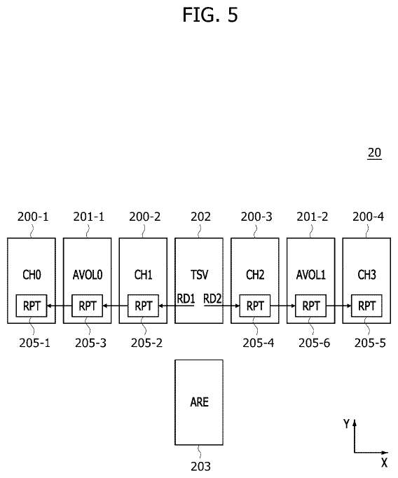

The first channel region 200-1 includes a first memory cell array (not shown) in or from which data transmitted and received through a first channel (not shown) is stored or outputted in a normal operation. The first channel region 200-1 includes a first repeater 205-1 that receives first fuse data, for example, FD1 in FIG. 4, stored in the fuse data storage circuit 203 through the second channel region 200-2 and the first power supply region 201-1 and amplifies the received first fuse data during a boot-up operation. The boot-up operation is performed by transmitting or transferring the first fuse data and second fuse data, for example, FD2 in FIG. 4, stored in the fuse data storage circuit 203 implemented as an array e-fuse to the first channel region 200-1, the second channel region 200-2, the third channel region 200-3, and the fourth channel region 200-4 and storing the first fuse data and the second fuse data. The first channel region 200-1 receives and stores the first fuse data transmitted from the fuse data storage circuit 203 during the boot-up operation. The first repeater 205-1 is implemented as a bidirectional repeater, receives the first fuse data from the first direction (X-axis direction), and amplifies the first fuse data. The first repeater 205-1 receives first repair data, for example, RD1 in FIG. 5, received through the transmission circuit 202 and amplifies the first repair data for a repair operation. The transmission circuit 202 includes a plurality of through-vias that transmit or transfer the first repair data from the base die 100 shown in FIG. 1 to the core die 20. The first repair data includes information about locations of repaired memory cells and replaced redundancy cells, for example, slice ID for selecting a core die, an address for selecting a channel and a bank, and an address for defective memory cells. The repair operation may be a soft post package repair operation of replacing defective memory cells with redundancy memory cells. The first channel region 200-1 receives the first repair data transmitted from the base die 100 through the transmission circuit 202, the second channel region 200-2, and the first power supply region 201-1 and performs the repair operation. The first repeater 205-1 is implemented as a bidirectional repeater and receives the first repair data from the first direction (X-axis direction), meaning the first repeater 205-1 receives the first repair data from the right as illustrated.

The second channel region 200-2 includes a second memory cell array (not shown) in or from which data transmitted and received through a second channel (not shown) is stored or output in the normal operation. The second channel region 200-2 includes a second repeater 205-2 that receives and amplifies the first fuse data during the boot-up operation. The second channel region 200-2 receives and stores the first fuse data during the boot-up operation. The second repeater 205-2 is implemented as a bidirectional repeater, receives the first fuse data from the first direction, amplifies the received first fuse data, and then outputs the amplified first fuse data in the second direction (opposite to the X-axis). The second repeater 205-2 receives and amplifies the first repair data received through the transmission circuit 202 for the repair operation. The second channel region 200-2 receives the first repair data transmitted from the base die 100 through the transmission circuit 202 and performs the repair operation. The second repeater 205-2 is implemented as a bidirectional repeater, receives the first repair data from the first direction, amplifies the received first repair data, and then outputs the amplified first repair data in the second direction.

The first power supply region 201-1 is positioned between the first channel region 200-1 and the second channel region 200-2 and supplies internal power used in the first channel region 200-1 and the second channel region 200-2. The first power supply region 201-1 includes a third repeater 205-3 that receives the first fuse data from the second channel region 200-2, amplifies the received first fuse data, and then outputs the amplified first fuse data to the first channel region 200-1 during the boot-up operation. The third repeater 205-3 is implemented as a bidirectional repeater, receives the first fuse data from the first direction, amplifies the received first fuse data, and then outputs the amplified first fuse data in the second direction. The third repeater 205-3 receives the first repair data from the second channel region 200-2 for the repair operation, amplifies the received first repair data, and then outputs the amplified first repair data to the first channel region 200-1. The third repeater 205-3 is implemented as a bidirectional repeater, receives the first repair data from the first direction, amplifies the received first repair data, and then outputs the amplified first repair data in the second direction.

The third channel region 200-3 includes a third memory cell array (not shown) in or from which data transmitted and received through a third channel (not shown) is stored or output in the normal operation. The third channel region 200-3 includes a fourth repeater 205-4 that receives and amplifies the second fuse data stored in the fuse data storage circuit 203 during the boot-up operation. The third channel region 200-3 receives and stores the second fuse data transmitted from the fuse data storage circuit 203 during the boot-up operation. The fourth repeater 205-4 is implemented as a bidirectional repeater, receives the second fuse data from the second direction, amplifies the received second fuse data, and then outputs the amplified second fuse data in the first direction. The fourth repeater 205-4 receives and amplifies second repair data, for example, RD2 in FIG. 5, received through the transmission circuit 202 for the repair operation. The second repair data includes information about locations of repaired memory cells and replaced redundancy cells, for example, a slice ID for selecting a core die, an address for selecting a channel and a bank, and an address for defective memory cells. The third channel region 200-3 receives the second repair data transmitted from the base die 100 through the transmission circuit 202 and performs the repair operation. The fourth repeater 205-4 is implemented as a bidirectional repeater, receives the second repair data from the second direction, amplifies the received second repair data, and then outputs the amplified second repair data in the first direction.

The fourth channel region 200-4 includes a fourth memory cell array (not shown) in or from which data transmitted and received through a fourth channel (not shown) is stored or output in the normal operation. The fourth channel region 200-4 includes a fifth repeater 205-5 that receives and amplifies the second fuse data through the third channel region 200-3 and the second power supply region 201-2 during the boot-up operation. The fourth channel region 200-4 receives and stores the second fuse data transmitted from the fuse data storage circuit 203 during the boot-up operation. The fifth repeater 205-5 is implemented as a bidirectional repeater, receives the second fuse data from the second direction, and amplifies the received second fuse data. The fifth repeater 205-5 receives and amplifies the second repair data received through the transmission circuit 202 for the repair operation. The fourth channel region 200-4 receives the second repair data transmitted from the base die 100 through the transmission circuit 202, the third channel region 200-3, and the second power supply region 201-2 to perform the repair operation. The fifth repeater 205-5 is implemented as a bidirectional repeater, receives the second repair data from the second direction, and amplifies the received second repair data.

The second power supply region 201-2 is positioned between the third channel region 200-3 and the fourth channel region 200-4 and supplies internal power used in the third channel region 200-3 and the fourth channel region 200-4. The second power supply region 201-2 includes a sixth repeater 205-6 that receives the second fuse data from the third channel region 200-3, amplifies the received second fuse data, and then outputs the amplified second fuse data to the fourth channel region 200-4 during the boot-up operation. The sixth repeater 205-6 is implemented as a bidirectional repeater, receives the second fuse data from the second direction, amplifies the received second fuse data, and then outputs the amplified second fuse data in the first direction. The sixth repeater 205-6 receives the second repair data from the third channel region 200-3 for the repair operation, amplifies the received second repair data, and then outputs the amplified second repair data to the fourth channel region 200-4. The sixth repeater 205-6 is implemented as a bidirectional repeater, receives the second repair data from the second direction, amplifies the received second repair data, and then outputs the amplified second repair data in the first direction.

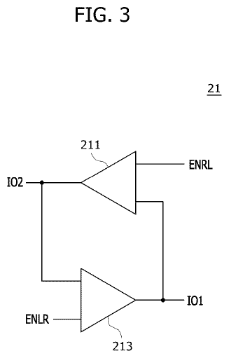

FIG. 3 illustrates a repeater 21 according to an embodiment of the present disclosure.

As shown in FIG. 3, the repeater 21 includes a first driver 211 and a second driver 213.

The first driver 211 drives a second input/output signal IO2 depending on a first input/output signal IO1 based on a first drive activation signal ENRL. The first drive activation signal ENRL is activated to amplify the first input/output signal IO1 received from the first direction to generate the second input/output signal IO2 and output the second input/output signal IO2 in the second direction. When the first drive activation signal ENRL is activated, the first driver 211 receives the first input/output signal IO1 from the first direction, amplifies the first input/output signal IO1 to generate the second input/output signal IO2, and outputs the second input/output signal IO2 in the second direction.

The second driver 213 drives the first input/output signal IO1 depending on the second input/output signal IO2 based on a second drive activation signal ENLR. The second drive activation signal ENLR is activated to amplify the second input/output signal IO2 received from the second direction to generate the first input/output signal IO1 and output the first input/output signal IO1 in the first direction. When the second drive activation signal ENLR is activated, the second driver 213 receives the second input/output signal IO2 from the second direction, amplifies the second input/output signal IO2 to generate the first input/output signal IO1, and outputs the first input/output signal IO1 in the first direction.

As described above, the repeater 21 is implemented as a bidirectional repeater, receives the first input/output signal IO1 from the first direction, amplifies the first input/output signal IO1 to generate the second input/output signal IO2, and outputs the second input/output signal IO2 in the second direction, or receives the second input/output signal IO2 from the second direction, amplifies the second input/output signal IO2 to generate the first input/output signal IO1, and outputs the first input/output signal IO1 in the first direction. Each of the first input/output signal IO1 and the second input/output signal IO2 may be fuse data or repair data. Each of the first repeater 205-1, the second repeater 205-2, and the third repeater 205-3 shown in FIG. 1 may be implemented as the repeater 21 that operates in a state where the first drive activation signal ENRL is activated and the second drive activation signal ENLR is deactivated. Each of the fourth repeater 205-4, the fifth repeater 205-5, and the sixth repeater 205-6 shown in FIG. 1 may be implemented as the repeater 21 that operates in a state where the first drive activation signal ENRL is deactivated and the second drive activation signal ENLR is activated.

FIG. 4 illustrates paths through which first fuse data FD1 and second fuse data FD2 are transmitted in a core die 20, for example, as shown in FIG. 2.

As shown in FIG. 4, when a boot-up operation is performed in the core die 20, the first fuse data FD1 stored in a fuse data storage circuit 203 is transmitted to and stored in the first channel region 200-1 and the second channel region 200-2. The second channel region 200-2 receives the first fuse data FD1 from the first direction (X-axis direction) through the second repeater 205-2, amplifies the received first fuse data FD1, and then stores the amplified first fuse data FD1. The third repeater 205-3 of the first power supply region 201-1 receives the first fuse data FD1 amplified by the second repeater 205-2 from the first direction, amplifies the received first fuse data FD1, and then outputs the amplified first fuse data FD1 to the first channel region 200-1. The first repeater 205-1 of the first channel region 200-1 receives the first fuse data FD1 amplified by the third repeater 205-3 from the first direction, amplifies the received first fuse data FD1, and then stores the amplified first fuse data FD1 in the first channel region 200-1.

As shown in FIG. 4, when the boot-up operation is performed in the core die 20, the second fuse data FD2 stored in the fuse data storage circuit 203 is transmitted to and stored in the third channel region 200-3 and the fourth channel region 200-4. The third channel region 200-3 receives the second fuse data FD2 from the second direction (opposite to the X-axis) through the fourth repeater 205-4, amplifies the received second fuse data FD2, and then stores the amplified second fuse data FD2. The sixth repeater 205-6 of the second power supply region 201-2 receives the second fuse data FD2 amplified by the fourth repeater 205-4 from the second direction, amplifies the received second fuse data FD2, and then outputs the amplified second fuse data FD2 to the fourth channel region 200-4. The fifth repeater 205-5 of the fourth channel region 200-4 receives the second fuse data FD2 amplified by the sixth repeater 205-6 from the second direction, amplifies received the second fuse data FD2, and then stores the second fuse data FD2 in the fourth channel region 200-4.

FIG. 5 illustrates paths through which first repair data RD1 and second repair data RD2 are transmitted in a second core die 20, for example, as shown in FIG. 2.

As shown in FIG. 5, in the core die 20, the first channel region 200-1 and the second channel region 200-2 receive the first repair data RD1 through the transmission circuit 202 and perform a repair operation. The second channel region 200-2 receives the first repair data RD1 from the first direction (X-axis direction) through the second repeater 205-2, amplifies the received first repair data RD1, and then performs the repair operation. The third repeater 205-3 of the first power supply region 201-1 receives the first repair data RD1 amplified by the second repeater 205-2 from the first direction, amplifies the received first repair data RD1 data, and then outputs the amplified first repair data RD1 to the first channel region 200-1. The first repeater 205-1 of the first channel region 200-1 receives the first repair data RD1 amplified by the third repeater 205-3 from the first direction, amplifies the received first repair data RD1, and then stores the amplified first repair data RD1 in the first channel region 200-1.

As shown in FIG. 5, in the core die 20, the third channel region 200-3 and the fourth channel region 200-4 receive the second repair data RD2 through the transmission circuit 202 and perform the repair operation. The third channel region 200-3 receives the second repair data RD2 through the fourth repeater 205-4 from the second direction (opposite to the X-axis), amplifies the received second repair data RD2, and then performs the repair operation. The sixth repeater 205-6 of the second power supply region 201-2 receives the second repair data RD2 amplified by the fourth repeater 205-4 from the second direction, amplifies the received second repair data RD2, and then outputs the amplified second repair data RD2 to the fourth channel region 200-4. The fifth repeater 205-5 of the fourth channel region 200-4 receives the second repair data RD2 amplified by the sixth repeater 205-6 from the second direction, amplifies the received second repair data RD2, and then stores the amplified second repair data RD2.

As described above, the core die 20 can transmit the first fuse data FD1 and the second fuse data FD2 for the boot-up operation and the first repair data RD1 and the second repair data RD2 received from the base die 100 through the transmission circuit 202 to the first to fourth channel regions 200-1 to 200-4 using the first to sixth repeaters 205-1 to 205-6 implemented as bidirectional repeaters.

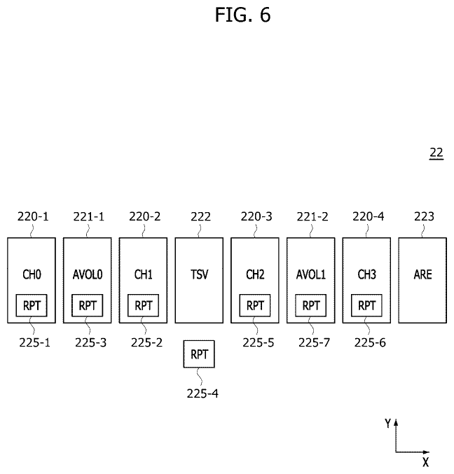

FIG. 6 illustrates a core die 22 according to an embodiment of the present disclosure.

As shown in FIG. 6, the core die 22 includes a first channel region (CH0) 220-1, a first power supply region (AVOL0) 221-1, a second channel region (CH1) 220-2, a third channel region (CH2) 220-3, a second power supply region (AVOL1) 221-2, a fourth channel region (CH3) 220-4, a transmission circuit (TSV) 222, and a fuse data storage circuit (ARE) 223.

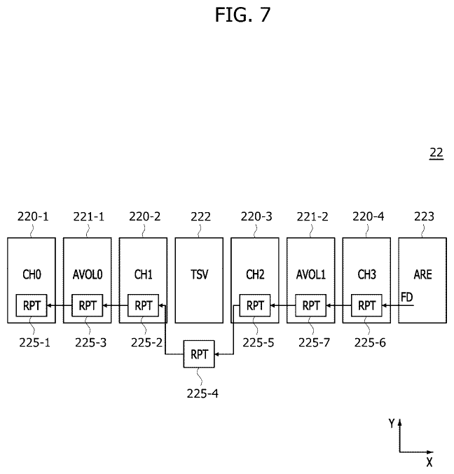

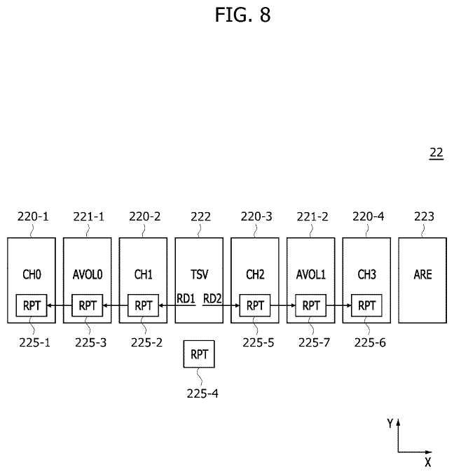

The first channel region 220-1 includes a first memory cell array (not shown) in or from which data transmitted and received through a first channel (not shown) is stored or output in a normal operation. The first channel region 220-1 includes a first repeater 225-1 that receives fuse data, for example, FD in FIG. 7, stored in the fuse data storage circuit 223 through the fourth channel region 220-4, the second power supply region 221-2, the third channel region 220-3, the fourth repeater 224-4, the second channel region 220-2, and the first power supply region 221-1 and amplifies the fuse data during a boot-up operation. The first channel region 220-1 receives and stores the fuse data transmitted from the fuse data storage circuit 223 during the boot-up operation. The first repeater 225-1 is implemented as a bidirectional repeater, receives the fuse data from the first direction (X-axis direction), and amplifies the received fuse data. The first repeater 225-1 receives first repair data, for example, RD1 in FIG. 8, received through the transmission circuit 222 and amplifies the first repair data for the repair operation. The transmission circuit 222 includes a plurality of through-vias for transmitting the first repair data from the base die 100 shown in FIG. 1 to the core die 22. The first channel region 220-1 receives the first repair data transmitted from the base die 100 through the transmission circuit 222, the second channel region 220-2, and the first power supply region 221-1 and performs the repair operation. The first repeater 225-1 is implemented as a bidirectional repeater and receives the first repair data from the first direction (X-axis direction).

The second channel region 220-2 includes a second memory cell array (not shown) in or from which data transmitted and received through the second channel (not shown) is stored or output in the normal operation. The second channel region 220-2 includes a second repeater 225-2 that receives the fuse data through the fourth channel region 220-4, the second power supply region 221-2, the third channel region 220-3, and the fourth repeater 225-4 and amplifies the fuse data during the boot-up operation. The second channel region 220-2 receives the fuse data and stores the fuse data during the boot-up operation. The second repeater 225-2 is implemented as a bidirectional repeater, receives the fuse data from the first direction, amplifies the received fuse data, and then outputs the amplified fuse data in the second direction (opposite to the X-axis). The second repeater 225-2 receives the first repair data received through the transmission circuit 222 and amplifies the received first repair data for the repair operation. The second channel region 220-2 receives the first repair data transmitted from the base die 100 through the transmission circuit 222 and performs the repair operation. The second repeater 225-2 is implemented as a bidirectional repeater, receives the first repair data from the first direction, amplifies the received first repair data, and then outputs the amplified first repair data in the second direction.

The first power supply region 221-1 is positioned between the first channel region 220-1 and the second channel region 220-2 and supplies internal power used in the first channel region 220-1 and the second channel region 220-2. The first power supply region 221-1 includes a third repeater 225-3 that receives the fuse data from the second channel region 220-2, amplifies the received fuse data, and outputs the amplified fuse data to the first channel region during the boot-up operation. The third repeater 225-3 is implemented as a bidirectional repeater, receives the fuse data from the first direction, amplifies the received fuse data, and then outputs the amplified fuse data in the second direction. The third repeater 225-3 receives the first repair data from the second channel region 220-2 for the repair operation, amplifies the received first repair data, and then outputs the amplified first repair data to the first channel region 220-1. The third repeater 225-3 is implemented as a bidirectional repeater, receives the first repair data from the first direction, amplifies the received first repair data, and then outputs the amplified first repair data in the second direction.

The fourth repeater 225-4 is implemented as a bidirectional repeater, receives the fuse data amplified by the fifth repeater 225-5 from the first direction, amplifies the received fuse data, and then outputs the amplified fuse data in the second direction to the second repeater 225-2 of the second channel region 220-2.

The third channel region 220-3 includes a third memory cell array (not shown) in or from which data transmitted and received through a third channel (not shown) is stored or output in the normal operation. The third channel region 220-3 includes a fifth repeater 225-5 that receives the fuse data stored in the fuse data storage circuit 223 through the fourth channel region 220-4 and the second power supply region 221-2 and amplifies the received the fuse data during the boot-up operation. During the boot-up operation, the third channel region 220-3 receives the fuse data transmitted from the fuse data storage circuit 223 and stores the received fuse data. The fifth repeater 225-5 is implemented as a bidirectional repeater, receives the fuse data from the first direction, amplifies the received fuse data, and then outputs the amplified fuse data in the second direction. The fifth repeater 225-5 receives second repair data, for example, RD2 in FIG. 8, received through the transmission circuit 222 for the repair operation and amplifies the received second repair data. The third channel region 220-3 receives the second repair data transmitted from the base die 100 through the transmission circuit 222 and performs the repair operation. The fifth repeater 225-5 is implemented as a bidirectional repeater, receives the second repair data from the second direction, amplifies the received second repair data, and then outputs the amplified second repair data in the first direction.

The fourth channel region 220-4 includes a fourth memory cell array (not shown) in or from which data transmitted and received through a fourth channel (not shown) is stored or output in the normal operation. The fourth channel region 220-4 includes a sixth repeater 225-6 that receives the fuse data stored in the fuse data storage circuit 223 and amplifies the received fuse data during the boot-up operation. The fourth channel region 220-4 receives the fuse data transmitted from the fuse data storage circuit 223 and stores the received fuse data during the boot-up operation. The sixth repeater 225-6 is implemented as a bidirectional repeater, receives the fuse data from the second direction, and amplifies the received fuse data. The sixth repeater 225-6 receives the second repair data received through the transmission circuit 222 and amplifies the received second repair data for the repair operation. The fourth channel region 220-4 receives the second repair data transmitted from the base die 100 through the transmission circuit 222, the third channel region 220-3, and the second power supply region 221-2 and performs the repair operation. The sixth repeater 225-6 is implemented as a bidirectional repeater, receives the second repair data from the second direction, and amplifies the received second repair data.

The second power supply region 221-2 is positioned between the third channel region 220-3 and the fourth channel region 220-4 and supplies internal power used in the third channel region 220-3 and the fourth channel region 220-4. The second power supply region 221-2 includes a seventh repeater 225-7 that receives the fuse data from the fourth channel region 220-4, amplifies the received fuse data, and then outputs the amplified fuse data to the third channel region 220-3 during the boot-up operation. The seventh repeater 225-7 is implemented as a bidirectional repeater, receives the fuse data from the second direction, amplifies the received fuse data, and then outputs the amplified fuse data in the first direction. The seventh repeater 225-7 receives the second repair data from the third channel region 220-3 for the repair operation, amplifies the received second repair data, and then outputs the amplified second repair data to the fourth channel region 220-4. The seventh repeater 225-7 is implemented as a bidirectional repeater, receives the second repair data from the second direction, amplifies the received second repair data, and then outputs the amplified second repair data in the first direction.

FIG. 7 illustrates a path through which fuse data FD is transmitted in a core die 22, for example, as shown in FIG. 6.

As shown in FIG. 7, when a boot-up operation is performed in the core die 22, the fuse data FD stored in the fuse data storage circuit 223 is transmitted to and stored in the first channel region 220-1, the second channel region 220-2, the third channel region 220-3, and the fourth channel region 220-4. The fourth channel region 220-4 receives the fuse data FD from the first direction (X-axis direction) through the sixth repeater 225-6, amplifies the received fuse data FD, and then stores the amplified fuse data FD. The seventh repeater 225-7 of the second power supply region 221-2 receives the fuse data FD amplified by the sixth repeater 225-6 from the first direction, amplifies the received fuse data FD, and then outputs the amplified fuse data FD to the third channel region 220-3. The fifth repeater 225-5 of the third channel region 220-3 receives the fuse data FD amplified by the seventh repeater 225-7 from the first direction, amplifies the received fuse data FD, and then stores the amplified fuse data FD in the third channel region 220-3. The fourth repeater 225-4 receives the fuse data FD amplified by the fifth repeater 225-5 from the first direction, amplifies the received fuse data FD, and then outputs the amplified fuse data FD to the second channel region 220-2. The second channel region 220-2 receives the fuse data FD through the second repeater 225-2 from the first direction, amplifies the received fuse data FD, and then stores the amplified fuse data FD. The third repeater 225-3 of the first power supply region 221-1 receives the fuse data FD amplified by the second repeater 225-2 from the first direction, amplifies the received fuse data FD, and then outputs the amplified fuse data FD to the first channel region 220-1. The first repeater 225-1 of the first channel region 220-1 receives the fuse data FD amplified by the third repeater 225-3 from the first direction, amplifies the received fuse data FD, and then stores the amplified fuse data FD in the first channel region 220-1.

FIG. 8 illustrates paths through which first repair data RD1 and second repair data RD2 are transmitted in a core die 22, for example, as shown in FIG. 6.

As shown in FIG. 8, in the core die 22, the first channel region 220-1 and the second channel region 220-2 receive the first repair data RD1 through the transmission circuit 222 to perform a repair operation. The second channel region 220-2 receives the first repair data RD1 from the first direction (X-axis direction) through the second repeater 225-2, amplifies the received first repair data RD1, and then performs the repair operation. The third repeater 225-3 of the first power supply region 221-1 receives the first repair data RD1 amplified by the second repeater 225-2 from the first direction, amplifies the received first repair data RD1, and then outputs the amplified first repair data RD1 to the first channel region 220-1. The first repeater 225-1 of the first channel region 220-1 receives the first repair data RD1 amplified by the third repeater 225-3 from the first direction, amplifies the received first repair data RD1, and then stores the amplified first repair data RD1 in the first channel region 220-1.

As shown in FIG. 8, in the core die 22, the third channel region 220-3 and the fourth channel region 220-4 receive the second repair data RD2 through the transmission circuit 222 to perform the repair operation. The third channel region 220-3 receives the second repair data RD2 through the fifth repeater 225-5 from the second direction (opposite to the X-axis), amplifies the received second repair data RD2, and then performs the repair operation. The seventh repeater 225-7 of the second power supply region 221-2 receives the second repair data RD2 amplified by the fifth repeater 225-5 from the second direction, amplifies the received second repair data RD2, and then outputs the amplified second repair data RD2 to the fourth channel region 220-4. The sixth repeater 225-6 of the fourth channel region 220-4 receives the second repair data RD2 amplified by the seventh repeater 205-7 from the second direction, amplifies the received second repair data RD2 data, and then stores the amplified second repair data RD2.

As described above, the core die 22 can transmit the fuse data FD for a boot-up operation and the first repair data RD1 and the second repair data RD2 received from the base die 100 through the transmission circuit 222 to the first to fourth channel regions 220-1 to 220-4 using the first to sixth repeaters 225-1 to 225-6 implemented as bidirectional repeaters.

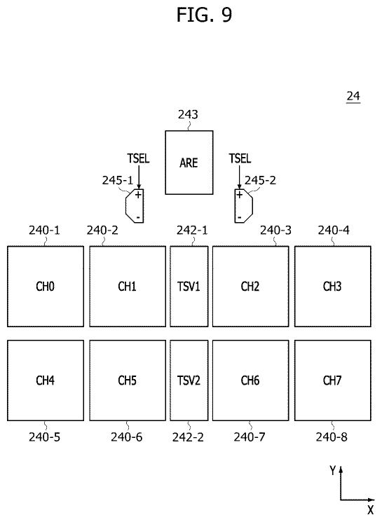

FIG. 9 illustrates a core die 24 according to an embodiment of the present disclosure.

As shown in FIG. 9, the core die 24 includes a first channel region (CH0) 240-1, a second channel region (CH1) 240-2, a third channel region (CH2) 240-3, a fourth channel region (CH3) 240-4, a fifth channel region (CH4) 240-5, a sixth channel region (CH5) 240-6, a seventh channel region (CH6) 240-7, an eighth channel region (CH7) 240-8, a first transmission circuit (TSV1) 242-1, a second transmission circuit (TSV2) 242-2, a fuse data storage circuit (ARE) 243, a first selection circuit 245-1, and a second selection circuit 245-2.

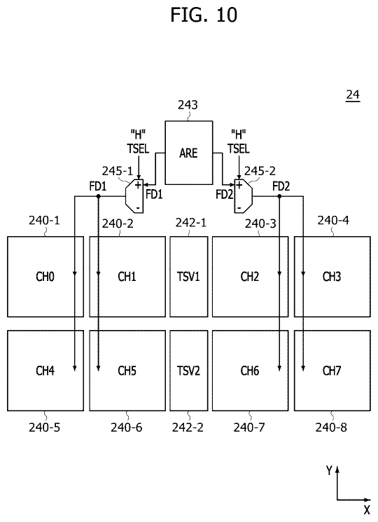

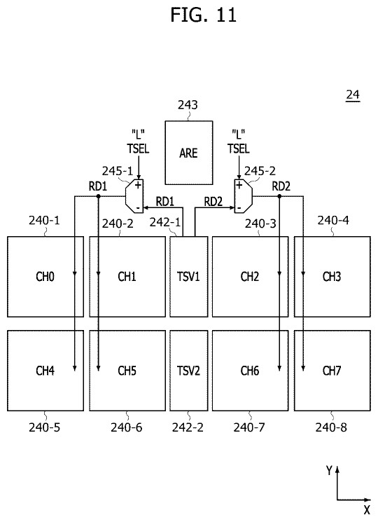

The first channel region 240-1 includes a first memory cell array (not shown) in or from which data transmitted and received through a first channel (not shown) is stored or output in a normal operation. The first channel region 240-1 receives first fuse data, for example, FD1 in FIG. 10, stored in the fuse data storage circuit 243 through the first selection circuit 245-1 and stores the first fuse data during a boot-up operation. The first channel region 240-1 receives first repair data, for example, RD1 in FIG. 11, through the first transmission circuit 242-1 (or the second transmission circuit 242-2) and the first selection circuit 245-1 and performs a repair operation. The first channel region 240-1 receives the first fuse data from a third direction (Y-axis direction) during the boot-up operation and receives the first repair data from the third direction for the repair operation.

The second channel region 240-2 includes a second memory cell array (not shown) in or from which data transmitted and received through a second channel (not shown) is stored or output in a normal operation. The second channel region 240-2 receives the first fuse data through the first selection circuit 245-1 and stores the first fuse data during a boot-up operation. The second channel region 240-2 receives the first repair data through the first transmission circuit 242-1 (or the second transmission circuit 242-2) and the first selection circuit 245-1 and performs a repair operation. The second channel region 240-2 receives the first fuse data from the third direction during the boot-up operation and receives the first repair data from the third direction for a repair operation.

The third channel region 240-3 includes a third memory cell array (not shown) in or from which data transmitted and received through a third channel (not shown) is stored or output in a normal operation. The third channel region 240-3 receives second fuse data, for example, FD2 in FIG. 10, through the second selection circuit 245-2 and stores the second fuse data during a boot-up operation. The third channel region 240-3 receives second repair data, for example, RD2 in FIG. 11, through the first transmission circuit 242-1 (or the second transmission circuit 242-2) and the second selection circuit 245-2 and performs a repair operation. The third channel region 240-3 receives the second fuse data from the third direction during a boot-up operation and receives the second repair data from the third direction for a repair operation.

The fourth channel region 240-4 includes a fourth memory cell array (not shown) in or from which data transmitted and received through a fourth channel (not shown) is stored or output in a normal operation. The fourth channel region 240-4 receives the second fuse data through the second selection circuit 245-2 and stores the second fuse data during a boot-up operation. The fourth channel region 240-4 receives the second repair data through the first transmission circuit 242-1 (or the second transmission circuit 242-2) and the second selection circuit 245-2 and performs a repair operation. The fourth channel region 240-4 receives the second fuse data from the third direction during a boot-up operation and receives the second repair data from the third direction for a repair operation.

The fifth channel region 240-5 includes a fifth memory cell array (not shown) in or from which data transmitted and received through a fifth channel (not shown) is stored or output in a normal operation. The fifth channel region 240-5 receives the first fuse data stored in the fuse data storage circuit 243 through the first selection circuit 245-1 and stores the first fuse data during a boot-up operation. The fifth channel region 240-5 receives the first repair data through the first transmission circuit 242-1 (or the second transmission circuit 242-2) and performs a repair operation. The fifth channel region 240-5 receives the first fuse data from the third direction during a boot-up operation and receives the first repair data from the third direction for a repair operation.

The sixth channel region 240-6 includes a sixth memory cell array (not shown) in or from which data transmitted and received through a sixth channel (not shown) is stored or output in a normal operation. The sixth channel region 240-6 receives the first fuse data through the first selection circuit 245-1 and stores the first fuse data during a boot-up operation. The sixth channel region 240-6 receives the first repair data through the first transmission circuit 242-1 (or the second transmission circuit 242-2) and the first selection circuit 245-1 and performs a repair operation. The sixth channel region 240-6 receives the first fuse data from the third direction during a boot-up operation and receives the first repair data from the third direction for a repair operation.

The seventh channel region 240-7 includes a seventh memory cell array (not shown) in or from which data transmitted and received through a seventh channel (not shown) is stored or output in a normal operation. The seventh channel region 240-7 receives the second fuse data through the second selection circuit 245-2 and stores the second fuse data during a boot-up operation. The seventh channel region 240-7 receives the second repair data through the first transmission circuit 242-1 (or the second transmission circuit 242-2) and the second selection circuit 245-2 and performs a repair operation. The seventh channel region 240-7 receives the second fuse data from the third direction during a boot-up operation and receives the second repair data from the third direction for a repair operation.

The eighth channel region 240-8 includes an eighth memory cell array (not shown) in or from which data transmitted and received through an eighth channel (not shown) is stored or output in a normal operation. The eighth channel region 240-8 receives the second fuse data through the second selection circuit 245-2 and stores the second fuse data during a boot-up operation. The eighth channel region 240-8 receives the second repair data through the first transmission circuit 242-1 (or the second transmission circuit 242-2) and the second selection circuit 245-2 and performs a repair operation. The eighth channel region 240-8 receives the second fuse data from the third direction during a boot-up operation and receives the second repair data from the third direction for a repair operation.

The first selection circuit 245-1 selectively transmits one of the first fuse data received from the fuse data storage circuit 243 and the first repair data received through the first transmission circuit 242-1 (or the second transmission circuit 242-2) to the first channel region 240-1, the second channel region 240-2, the fifth channel region 240-5, and the sixth channel region 240-6 based on a selection signal TSEL. The first selection circuit 245-1 transmits the first fuse data received through a “+” terminal to the first channel region 240-1, the second channel region 240-2, the fifth channel region 240-5, and the sixth channel region 240-6 when a boot-up operation is performed and the selection signal TSEL of a first logic level, for example, a logic “high” level, is received. The first selection circuit 245-1 transmits the first repair data received through a “−” terminal to the first channel region 240-1, the second channel region 240-2, the fifth channel region 240-5, and the sixth channel region 240-6 when the selection signal TSEL of a second logic level, for example, a logic “low” level, is received for a repair operation.

The second selection circuit 245-2 selectively transmits one of the second fuse data received from the fuse data storage circuit 243 and the second repair data received through the first transmission circuit 242-1 (or the second transmission circuit 242-2) to the third channel region 240-3, the fourth channel region 240-4, the seventh channel region 240-7, and the eighth channel region 240-8, based on the selection signal TSEL. The second selection circuit 245-2 transmits the second fuse data received through a “+” terminal to the third channel region 240-3, the fourth channel region 240-4, the seventh channel region 240-7, and the eighth channel region 240-8 when the boot-up operation is performed and the selection signal TSEL of the first logic level, for example, the logic high level, is received. The second selection circuit 245-2 transmits the second repair data received through a “−” terminal to the third channel region 240-3, the fourth channel region 240-4, the seventh channel region 240-7, and the eighth channel region 240-8 when the selection signal TSEL of the second logic level, for example, the logic low level, is received for the repair operation.

FIG. 10 illustrates paths through which first fuse data FD1 and second fuse data FD2 are transmitted in a core die 24, for example, as shown in FIG. 9.

As shown in FIG. 10, when a boot-up operation is performed in the core die 24, the first fuse data FD1 stored in the fuse data storage circuit 243 is transmitted to and stored in the first channel region 240-1, the second channel region 240-2, the fifth channel region 240-5, and the sixth channel region 240-6 through the first selection circuit 245-1. The first selection circuit 245-1 selects and outputs the first fuse data FD1 received through a “+” terminal when the boot-up operation is performed and the selection signal TSEL set at a logic high level “H” is received. The first channel region 240-1 receives the first fuse data FD1 from a third direction (Y-axis direction) and stores the first fuse data FD1. The second channel region 240-2 receives the first fuse data FD1 from the third direction and stores the first fuse data FD1. The fifth channel region 240-5 receives the first fuse data FD1 from the third direction and stores the first fuse data FD1. The sixth channel region 240-6 receives the first fuse data FD1 from the third direction and stores the first fuse data FD1.

As shown in FIG. 10, when the boot-up operation is performed in the core die 24, the second fuse data FD2 stored in the fuse data storage circuit 243 is transmitted to and stored in the third channel region 240-3, the fourth channel region 240-4, the seventh channel region 240-7, and the eighth channel region 240-8 through the second selection circuit 245-2. The second selection circuit 245-2 selects and outputs the second fuse data FD2 received through a “+” terminal when the boot-up operation is performed and the selection signal TSEL set at the logic high level “H” is received. The third channel region 240-3 receives the second fuse data FD2 in the third direction and stores the second fuse data FD2. The fourth channel region 240-4 receives the second fuse data FD2 from the third direction and stores the second fuse data FD2. The seventh channel region 240-7 receives the second fuse data FD2 from the third direction and stores the second fuse data FD2. The eighth channel region 240-8 receives the second fuse data FD2 from the third direction, amplifies the received second fuse data FD2, and then stores the amplified second fuse data FD2.

FIG. 11 illustrates paths through which first repair data RD1 and second repair data RD2 are transmitted in the core die 24, for example, as shown in FIG. 9.

As shown in FIG. 11, in the core die 24, the first channel region 240-1, the second channel region 240-2, the fifth channel region 240-5, and the sixth channel region 240-6 receive the first repair data RD1 through the first transmission circuit 242-1 and the first selection circuit 245-1 and perform a repair operation. The first selection circuit 245-1 selects and outputs the first repair data RD1 received through the “−” terminal when the selection signal TSEL set at a logic low level “L” is received for the repair operation. The first channel region 240-1 receives the first repair data RD1 from the third direction (Y-axis direction) and performs the repair operation. The second channel region 240-2 receives the first repair data RD1 from the third direction and performs the repair operation. The fifth channel region 240-5 receives the first repair data RD1 from the first direction and performs the repair operation. The sixth channel region 240-6 receives the first fuse data FD1 from the third direction and performs the repair operation.

As shown in FIG. 11, in the core die 24, the third channel region 240-3, the fourth channel region 240-4, the seventh channel region 240-7, and the eighth channel region 240-8 receive the second repair data RD2 through the first transmission circuit 242-1 and the second selection circuit 245-2 and perform the repair operation. The second selection circuit 245-2 selects and outputs the second repair data RD2 received through the “−” terminal when the selection signal TSEL set at a logic low level “L” is received for the repair operation. The third channel region 240-3 receives the second repair data RD2 from the third direction and performs the repair operation. The fourth channel region 240-4 receives the second repair data RD2 from the third direction and performs the repair operation. The seventh channel region 240-7 receives the second repair data RD2 from the third direction and performs the repair operation. The eighth channel region 240-8 receives the second repair data RD2 from the third direction and performs the repair operation.

As described above, in the core die 24, the fuse data storage circuit 243, the first transmission circuit 242-1, and the second transmission circuit 242-2 are positioned between the first channel region 240-1, the second channel region 240-2, the fifth channel region 240-5, the sixth channel region 240-6 and the third channel region 240-3, the fourth channel region 240-4, the seventh channel region 240-7, the eighth channel region 240-8, the first fuse data FD1 and the first repair data RD1 are selectively transmitted by the first selection circuit 245-1, and the second fuse data FD2 and the second repair data RD2 are selectively transmitted by the second selection circuit 245-2. Accordingly, the first fuse data FD1, the second fuse data FD2, the first repair data RD1, and the second repair data RD2 can be transmitted to the first channel region 240-1, the second channel region 240-2, the third channel region 240-3, the fourth channel region 240-4, the fifth channel region 240-5, the sixth channel region 240-6, the seventh channel region 240-7, and the eighth channel region 240-8.

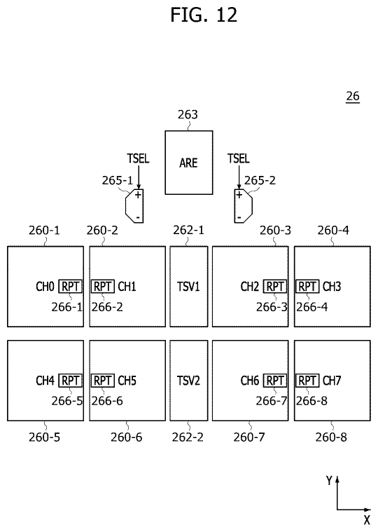

FIG. 12 illustrates a core die 26 according to an embodiment of the present disclosure.

As shown in FIG. 12, the core die 26 includes a first channel region (CH0) 260-1, a second channel region (CH1) 260-2, a third channel region (CH2) 260-3, a fourth channel region (CH3) 260-4, a fifth channel region (CH4) 260-5, a sixth channel region (CH5) 260-6, a seventh channel region (CH6) 260-7, an eighth channel region (CH7) 260-8, a first transmission circuit (TSV1) 262-1, a second transmission circuit (TSV2) 262-2, a fuse data storage circuit (ARE) 263, a first selection circuit 265-1, and a second selection circuit 265-2.

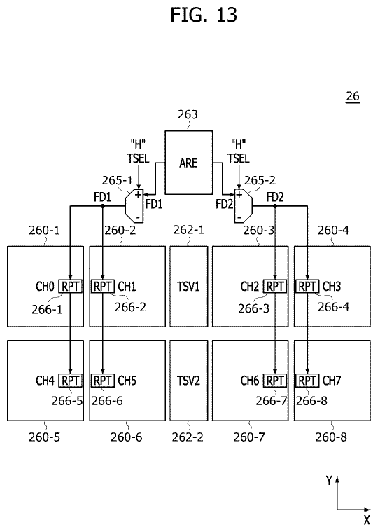

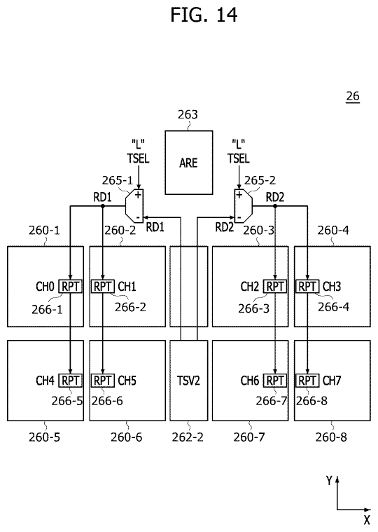

The first channel region 260-1 includes a first memory cell array (not shown) in or from which data transmitted and received through a first channel (not shown) is stored or output in a normal operation. The first channel region 260-1 includes a first repeater 266-1 that receives fuse data, for example, FD1 in FIG. 13, stored in the fuse data storage circuit 263 through the first selection circuit 265-1 and amplifies the fuse data during a boot-up operation. The first channel region 260-1 receives the first fuse data through the first selection circuit 265-1 and stores the first fuse data during the boot-up operation. The first repeater 266-1 is implemented as a unidirectional repeater, receives the first fuse data from a third direction (Y-axis direction), amplifies the received first fuse data, and then outputs the amplified first fuse data in a fourth direction (direction opposite to the Y-axis). The first repeater 266-1 receives first repair data, for example, RD1 in FIG. 14, received through the first transmission circuit 262-1 (or the second transmission circuit 262-2) and the first selection circuit 265-1 and amplifies the first repair data for a repair operation. The first channel region 260-1 receives the first repair data through the first transmission circuit 262-1 (or the second transmission circuit 262-2) and the first selection circuit 265-1 and performs the repair operation. The first repeater 266-1 is implemented as a unidirectional repeater, receives the first repair data from the third direction (Y-axis direction), amplifies the received first repair data, and then outputs the amplified first repair data in the fourth direction (opposite to the Y-axis).

The second channel region 260-2 includes a second memory cell array (not shown) in or from which data transmitted and received through a second channel (not shown) is stored or output in a normal operation. The second channel region 260-2 includes a second repeater 266-2 that receives the first fuse data through the first selection circuit 265-1 and amplifies the first fuse data during a boot-up operation. The second channel region 260-2 receives the first fuse data through the first selection circuit 265-1 and stores the first fuse data during the boot-up operation. The second repeater 266-2 is implemented as a unidirectional repeater, receives the first fuse data from the third direction, amplifies the received first data, and then outputs the amplified first fuse data in the fourth direction. The second repeater 266-2 receives and amplifies the first repair data for a repair operation. The second channel region 260-2 receives the first repair data through the first transmission circuit 262-1 (or the second transmission circuit 262-2) and the first selection circuit 265-1 to perform the repair operation. The second repeater 266-2 is implemented as a unidirectional repeater, receives the first repair data from the third direction, amplifies the received first repair data, and then outputs the amplified first repair data in the fourth direction.

The third channel region 260-3 includes a third memory cell array (not shown) in or from which data transmitted and received through a third channel (not shown) is stored or output in a normal operation. The third channel region 260-3 includes a third repeater 266-3 that receives second fuse data, for example, FD2 in FIG. 13, through the second selection circuit 265-2 and amplifies the received second fuse data during a boot-up operation. The third channel region 260-3 receives the second fuse data through the second selection circuit 265-2 and stores the second fuse data during the boot-up operation. The third repeater 266-3 is implemented as a unidirectional repeater, receives the second fuse data from the third direction, amplifies the received second fuse data, and then outputs the amplified second fuse data in the fourth direction. The third repeater 266-3 receives and amplifies second repair data for a repair operation. The third channel region 260-3 receives the second repair data through the first transmission circuit 262-1 (or the second transmission circuit 262-2) and the second selection circuit 265-2 and performs the repair operation. The third repeater 266-3 is implemented as a unidirectional repeater, receives the first repair data from the third direction, amplifies the received first repair data, and then outputs the amplified first repair data in the fourth direction.

The fourth channel region 260-4 includes a fourth memory cell array (not shown) in or from which data transmitted and received through a fourth channel (not shown) is stored or output in the normal operation. The fourth channel region 260-4 includes a fourth repeater 266-4 that receives the second fuse data through the second selection circuit 265-2 and amplifies the second fuse data during the boot-up operation. The fourth channel region 260-4 receives the second fuse data through the second selection circuit 265-2 and stores the second fuse data. The fourth repeater 266-4 is implemented as a unidirectional repeater, receives the second fuse data from the third direction, amplifies the received second fuse data, and then outputs the amplified second fuse data in the fourth direction. The fourth repeater 266-4 receives and amplifies the second repair data for the repair operation. The fourth channel region 260-4 receives the second repair data through the first transmission circuit 262-1 (or the second transmission circuit 262-2) and the second selection circuit 265-2 and performs the repair operation. The fourth repeater 266-4 is implemented as a unidirectional repeater, receives the second repair data from the third direction, amplifies the received second repair data, and then outputs the amplified second repair data in the fourth direction.

The fifth channel region 260-5 includes a fifth memory cell array (not shown) in or from which data transmitted and received through a fifth channel (not shown) is stored or output in the normal operation. The fifth channel region 260-5 includes a fifth repeater 266-5 that receives the first fuse data through the first selection circuit 265-1 and amplifies the first fuse data during the boot-up operation. The fifth channel region 260-5 receives the first fuse data through the first selection circuit 265-1 and stores the first fuse data. The fifth repeater 266-5 is implemented as a unidirectional repeater, receives the first fuse data from the third direction, and amplifies the received first fuse data. The fifth repeater 266-5 receives and amplifies the first repair data for the repair operation. The fifth channel region 260-5 receives the first repair data through the first transmission circuit 262-1 (or the second transmission circuit 262-2) and the first selection circuit 265-1 and performs the repair operation. The fifth repeater 266-5 is implemented as a unidirectional repeater and receives the second repair data from the third direction.

The sixth channel region 260-6 includes a sixth memory cell array (not shown) in or from which data transmitted and received through a sixth channel (not shown) is stored or output in the normal operation. The sixth channel region 260-6 includes a sixth repeater 266-6 that receives the first fuse data through the first selection circuit 265-1 and amplifies the first fuse data during the boot-up operation. The sixth channel region 260-6 receives the first fuse data through the first selection circuit 265-1 and stores the first fuse data. The sixth repeater 266-6 is implemented as a unidirectional repeater, receives the first fuse data from the third direction, and amplifies the received first fuse data. The sixth repeater 266-6 receives and amplifies the first repair data for the repair operation. The sixth channel region 260-6 receives the first repair data through the first transmission circuit 262-1 (or the second transmission circuit 262-2) and the first selection circuit 265-1 and performs the repair operation. The sixth repeater 266-6 is implemented as a unidirectional repeater and receives the second repair data from the third direction.

The seventh channel region 260-7 includes a seventh memory cell array (not shown) in or from which data transmitted and received through a seventh channel (not shown) is stored or output in the normal operation. The seventh channel region 260-7 includes a seventh repeater 266-7 that receives the second fuse data through the second selection circuit 265-2 and amplifies the second fuse data during the boot-up operation. The seventh channel region 260-7 receives the second fuse data through the second selection circuit 265-2 and stores the first fuse data during the boot-up operation. The seventh repeater 266-7 is implemented as a unidirectional repeater, receives the second fuse data from the third direction, and amplifies the received second fuse data. The seventh repeater 266-7 receives and amplifies the second repair data for the repair operation. The seventh channel region 260-7 receives the second repair data through the first transmission circuit 262-1 (or the second transmission circuit 262-2) and the second selection circuit 265-2 and performs the repair operation. The seventh repeater 266-7 is implemented as a unidirectional repeater and receives the first repair data from the third direction.

The eighth channel region 260-8 includes an eighth memory cell array (not shown) in or from which data transmitted and received through an eighth channel (not shown) is stored or output in the normal operation. The eighth channel region 260-8 includes an eighth repeater 266-8 that receives the second fuse data through the second selection circuit 265-2 and amplifies the second fuse data during the boot-up operation. The eighth channel region 260-8 receives the second fuse data through the second selection circuit 265-2 and stores the second fuse data during the boot-up operation. The eighth repeater 266-8 is implemented as a unidirectional repeater, receives the second fuse data from the third direction, and amplifies the received second fuse data. The eighth repeater 266-8 receives and amplifies the second repair data for the repair operation. The eighth channel region 260-8 receives the second repair data through the first transmission circuit 262-1 (or the second transmission circuit 262-2) and the second selection circuit 265-2 and performs the repair operation. The eighth repeater 266-8 is implemented as a unidirectional repeater and receives the second repair data from the third direction.

The first selection circuit 265-1 selectively transmits one of the first fuse data received from the fuse data storage circuit 263 and the first repair data received through the first transmission circuit 262-1 (or the second transmission circuit 262-2) to the first channel region 260-1, the second channel region 260-2, the fifth channel region 260-5, and the sixth channel region 260-6, based on a selection signal TSEL. The first selection circuit 265-1 transmits the first fuse data received through a “+” terminal to the first channel region 260-1, the second channel region 260-2, the fifth channel region 260-5, and the sixth channel region 260-6 when the boot-up operation is performed and the selection signal TSEL of a first logic level, for example, a logic high level, is received. The first selection circuit 265-1 transmits the first repair data received through a “−” terminal to the first channel region 260-1, the second channel region 260-2, the fifth channel region 260-5, and the sixth channel region 260-6 when the selection signal TSEL of a second logic level, for example, a logic low level, is received for the repair operation.

The second selection circuit 265-2 selectively transmits one of the second fuse data received from the fuse data storage circuit 263 and the second repair data received through the first transmission circuit 262-1 (or the second transmission circuit 262-2) to the third channel region 260-3, the fourth channel region 260-4, the seventh channel region 260-7, and the eighth channel region 260-8, based on the selection signal TSEL. The second selection circuit 265-2 transmits the second fuse data received through a “+” terminal to the third channel region 260-3, the fourth channel region 260-4, the seventh channel region 260-7, and the eighth channel region 260-8 when the boot-up operation is performed and the selection signal TSEL of the first logic level, for example, a logic high level, is received. The second selection circuit 265-2 transmits the second repair data received through a “−” terminal to the third channel region 260-3, the fourth channel region 260-4, the seventh channel region 260-7, and the eighth channel region 260-8 when the selection signal TSEL of the second logic level, for example, a logic low level, is received for the repair operation.

FIG. 13 illustrates paths through which first fuse data FD1 and second fuse data FD2 are transmitted in a core die 26, for example, as shown in FIG. 12.

As shown in FIG. 13, when a boot-up operation is performed in the core die 26, the first fuse data FD1 stored in the fuse data storage circuit 263 is transmitted to and stored in the first channel region 260-1, the second channel region 260-2, the fifth channel region 260-5, and the sixth channel region 260-6 through the first selection circuit 265-1. The first selection circuit 265-1 selects and outputs the first fuse data FD1 received through a “+” terminal when the selection signal TSEL set at a logic high level “H” is received. The first channel region 260-1 receives the first fuse data FD1 from a third direction (Y-axis direction) through the first repeater 266-1, amplifies the received first fuse data FD1, and then stores the amplified first fuse data FD1. The second channel region 260-2 receives the first fuse data FD1 from the third direction through the second repeater 266-2, amplifies the received first fuse data FD1, and then stores the amplified first fuse data FD1. The fifth channel region 260-5 receives the first fuse data FD1 from the third direction through the fifth repeater 266-5, amplifies the received first fuse data FD1, and then stores the amplified first fuse data FD1. The sixth channel region 260-6 receives the first fuse data FD1 from the third direction through the sixth repeater 266-6, amplifies the received first fuse data FD1, and then stores the amplified first fuse data FD1.

As shown in FIG. 13, when the boot-up operation is performed in the core die 26, the second fuse data FD2 stored in the fuse data storage circuit 263 is transmitted to and stored in the third channel region 260-3, the fourth channel region 260-4, the seventh channel region 260-7, and the eighth channel region 260-8 through the second selection circuit 265-2. The second selection circuit 265-2 selects and outputs the second fuse data FD2 received through a “+” terminal when the selection signal TSEL set at a logic high level “H” is received. The third channel region 260-3 receives the second fuse data FD2 from the third direction (Y-axis direction) through the third repeater 266-3, amplifies the received second fuse data FD2, and then stores the amplified second fuse data FD2. The fourth channel region 260-4 receives the second fuse data FD2 from the third direction through the fourth repeater 266-4, amplifies the received second fuse data FD2, and then stores the amplified second fuse data FD2. The seventh channel region 260-7 receives the second fuse data FD2 from the third direction through the seventh repeater 266-7, amplifies the received second fuse data FD2, and then stores the amplified second fuse data FD2. The eighth channel region 260-8 receives the second fuse data FD2 from the third direction through the eighth repeater 266-8, amplifies the received second fuse data FD2, and then stores the amplified second fuse data FD2.

FIG. 14 illustrates paths through which first repair data RD1 and second repair data RD2 are transmitted in a core die 26, for example, as shown in FIG. 12.

As shown in FIG. 14, in the core die 26, the first channel region 260-1, the second channel region 260-2, the fifth channel region 260-5, and the sixth channel region 260-6 receive the first repair data RD1 through the second transmission circuit 262-2 and the first selection circuit 265-1 and perform a repair operation. The first selection circuit 265-1 selects and outputs the first repair data RD1 received through a “−” terminal when the selection signal TSEL set at a logic low level “L” is received. The first channel region 260-1 receives the first repair data RD1 from the third direction (Y-axis direction) through the first repeater 266-1 and performs the repair operation. The second channel region 260-2 receives the first repair data RD1 from the third direction (Y-axis direction) through the second repeater 266-2 and performs the repair operation. The fifth channel region 260-5 receives the first repair data RD1 from the third direction (Y-axis direction) through the fifth repeater 266-5 and performs the repair operation. The sixth channel region 260-6 receives the first repair data RD1 from the third direction (Y-axis direction) through the sixth repeater 266-6 and performs the repair operation.

As shown in FIG. 14, in the core die 26, the third channel region 260-3, the fourth channel region 260-4, the seventh channel region 260-7, and the eighth channel region 260-8 receive the second repair data RD2 through the second transmission circuit 262-2 and the second selection circuit 265-2 and perform the repair operation. The second selection circuit 265-2 selects and outputs the second repair data RD2 received through the “−” terminal when the selection signal TSEL set at a logic low level “L” is received. The third channel region 260-3 receives the second repair data RD2 from the third direction through the third repeater 266-3 and performs the repair operation. The fourth channel region 260-4 receives the second repair data RD2 from the third direction through the fourth repeater 266-4 and performs the repair operation. The seventh channel region 260-7 receives the second repair data RD2 from the third direction through the seventh repeater 266-7 and performs the repair operation. The eighth channel region 260-8 receives the second repair data RD2 from the third direction through the eighth repeater 266-8 and performs the repair operation.

As described above, in the core die 26, the fuse data storage circuit 263, the first transmission circuit 262-1, and the second transmission circuit 262-2 are positioned between the first channel region 260-1, the second channel region 260-2, the fifth channel region 260-5 and the sixth channel region 260-6 and the third channel region 260-3, the fourth channel region 260-4, the seventh channel region 260-7 and the eighth channel region 260-8, the first fuse data FD1 and the first repair data RD1 are selectively transmitted by the first selection circuit 265-1, and the second fuse data FD2 and the second repair data RD2 are selectively transmitted by the second selection circuit 265-2. Accordingly, the first fuse data FD1, the second fuse data FD2, the first repair data RD1, and the second repair data RD2 can be transmitted to the first channel region 260-1, the second channel region 260-2, the third channel region 260-3, the fourth channel region 260-4, the fifth channel region 260-5, the sixth channel region 260-6, the seventh channel region 260-7, and the eighth channel region 260-8 using the first to eighth repeaters 266-1 to 266-8 implemented as unidirectional repeaters.

FIG. 15 illustrates a memory system 3 according to an embodiment of the present disclosure.

As shown in FIG. 15, the memory system 3 includes a printed circuit board (PCB) 31, a substrate 33, an interposer 35, a memory device 37, and a processor 39.

The printed circuit board 31 connects various electronic components to each other to form an electronic circuit (not shown). The electronic circuit includes the memory system 3. A copper (Cu) layer, a solder mask, a silkscreen, and so forth are formed on the printed circuit board 31. The copper (Cu) layer forms a circuit path that transmits or transfers signals or power. The solder mask prevents damage to the circuit and protects specific regions where components are soldered. The silkscreen indicates locations or information for the electronic components as characters or symbols printed on a surface of the printed circuit board 31.

The substrate 33 is disposed over the printed circuit board 31 with bump pads in between, for example, bump pads 311 that mechanically support the substrate 33 and the interposer 35. The substrate 33 functions as a physical base for the printed circuit board 31 and is an insulator. The substrate 33 may include materials, such as FR4 that is an insulator made of fiberglass and epoxy resin; ceramics that can withstand high temperatures, have appropriate thermal conductivity properties, and are used in high-frequency circuits; polyimide that is used as a basic material for flexible PCBs due to flexible characteristics; and the like.

The interposer 35 is disposed over the substrate 33 with bump pads in between and includes interconnections that connect electronic components, for example, the memory device 37 and the processor 39, that have form factors or pin arrangements do not match or have different spacing. The interposer 35 converts signals for communication across different interfaces, such as DDR, HBM, and PCIe.

The memory device 37 is disposed over the interposer 35 with paths in between, for example, micro-bump pads 313. The memory device 37 stores data received from the processor 39 or outputs the stored data to the processor 39 under the control of the processor 39. The memory device 37 includes a base die 320 and a plurality of core dies 321-1 to 321-L, where L is an integer greater than 1. The core dies 321-1 to 321-L are stacked over the base die 320 with the micro-bump pads in between. The base die 320 and the core dies 321-1 to 321-L are vertically connected to each other using through-vias and micro-bump pads. The base die 320 controls data transmission between the processor 39 and the core dies 321-1 to 321-L. The base die 320 receives input/output power voltage (voltage drain for IO also referred to as output stage drain power voltage) VDDQ as an operating voltage utilized during operation of internal circuits included in the base die 320. The base die 320 receives the input/output power voltage VDDQ from the printed circuit board 31 through the substrate 33 and the interposer 35. The input/output power voltage VDDQ is a voltage supplied to buffers that transmit data and is distinguished or different from the power supply voltage VDD. The core dies 321-1 to 321-L use a peripheral voltage VPERI as an operating voltage during operation of the internal circuits included in the core dies 321-1 to 321-L. The core dies 321-1 to 321-L generate the peripheral voltage VPERI from the input/output power voltage VDDQ received through the base die 320. The core dies 321-1 to 321-L generate the peripheral voltage VPERI at a lower voltage level than the input/output power voltage VDDQ and use the peripheral voltage VPERI as an operating voltage. Each of the core dies 321-1 to 321-L includes a plurality of channel regions, for example, eight channel regions or sixteen channel regions that operate independently. Each of the plurality of channel regions is allocated with a channel operating independently to receive or transmit data. The number L of core dies 321-1 to 321-L may be four, eight, twelve, sixteen, and so forth. For example, when each of the core dies 321-1 to 321-12 has eight channels, the core dies 321-1 to 321-4, the core dies 321-5 to 321-8, and the core dies 321-9 to 321-12 each include thirty two channel regions, and transmit and receive data with the processor 19 in units of a rank including thirty two channels.

Concepts are disclosed in conjunction with various examples and embodiments. Those skilled in the art will understand that various modifications, additions, and/or substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory device comprising a plurality of core dies stacked over a base die,
wherein each of the plurality of core dies comprises:
a first channel region comprising a first repeater configured to receive and amplify first fuse data stored in a fuse data storage circuit during a boot-up operation; and
a second channel region comprising a second repeater configured to receive and amplify second fuse data stored in the fuse data storage circuit during the boot-up operation,
wherein the first repeater is configured to receive first repair data transmitted from the base die through a transmission circuit and amplify the first repair data.

2. The memory device of claim 1, wherein the first repeater is configured to:
receive the first fuse data from a first direction, amplify the first fuse data, and output the amplified first fuse data in a second direction different from the first direction; and
receive the first repair data from the first direction, amplify the first repair data, and output the amplified first repair data in the second direction.

3. The memory device of claim 2, wherein the second direction is opposite to the first direction.

4. The memory device of claim 1, wherein the second repeater is configured to receive second repair data transmitted from the base die through the transmission circuit and amplify the second repair data.

5. The memory device of claim 4, wherein the second repeater is configured to:
receive the second fuse data from a second direction, amplify the second fuse data, and then output the amplified second fuse data in a first direction different from the second direction; and
receive the second repair data from the second direction, amplify the second repair data, and then output the amplified second repair data in the first direction.

6. The memory device of claim 1,
further comprising a third channel region comprising a third repeater configured to receive and amplify the first fuse data during the boot-up operation,
wherein the third repeater is configured to receive and amplify the first repair data.

7. The memory device of claim 6,
further comprising a first power supply region positioned between the first channel region and the third channel region,
wherein the first power supply region comprises a fourth repeater configured to receive the first fuse data amplified by the first repeater, amplify the first fuse data, and then output the amplified first fuse data to the third channel region; and
wherein the fourth repeater is configured to receive the first repair data amplified by the first repeater, amplify the first repair data, and then output the amplified first repair data to the third channel region.

8. The memory device of claim 6,
further comprising a fourth channel region comprising a fourth repeater configured to receive and amplify the second fuse data during the boot-up operation,
wherein the fourth repeater is configured to receive and amplify second repair data transmitted from the base die.

9. The memory device of claim 8,
further comprising a second power supply region positioned between the second channel region and the fourth channel region,
wherein the second power supply region comprises a fifth repeater configured to receive the second fuse data amplified by the second repeater, amplify the second fuse data, and then output the amplified second fuse data to the fourth channel region; and
wherein the fifth repeater is configured to receive the second repair data amplified by the second repeater, amplify the second repair data, and then output the amplified second repair data to the fourth channel region.

10. A memory device comprising a plurality of core dies stacked over a base die,
wherein each of the plurality of core dies comprises:
a first channel region comprising a first repeater configured to receive first fuse data stored in a fuse data storage circuit from a first direction and amplify the first fuse data during a boot-up operation; and
a second channel region comprising a second repeater configured to receive second fuse data stored in the fuse data storage circuit from the first direction and amplify the second fuse data during the boot-up operation;
wherein the first repeater is configured to receive first repair data transmitted from the base die through a transmission circuit from a second direction and amplify the first repair data; and
wherein the second repeater is configured to receive second repair data transmitted from the base die through the transmission circuit from the first direction and amplify the second repair data.

11. The memory device of claim 10, wherein the first repeater is configured to:
output the first fuse data in the second direction opposite to the first direction; and
output the first repair data in the first direction.

12. The memory device of claim 10, wherein the second repeater is configured to:
output the second fuse data in the second direction opposite to the first direction; and
output the second repair data in the second direction.

13. The memory device of claim 10, further comprising:
a third channel region comprising a third repeater configured to receive the first fuse data from the first direction and amplify the first fuse data during the boot-up operation; and
a fourth channel region comprising a fourth repeater configured to receive the second fuse data from the first direction and amplify the fuse data during the boot-up operation.

14. The memory device of claim 13, wherein the third repeater is configured to:
output the first fuse data in the second direction opposite to the first direction; and
output the first repair data in the first direction.

15. The memory device of claim 13, wherein the fourth repeater is configured to:
output the second fuse data in the second direction set opposite to the first direction; and
output the second repair data in the second direction.

16. A memory device comprising a plurality of core dies stacked over a base die,
wherein each of the plurality of core dies comprises:
a first selection circuit configured to selectively output one of first fuse data received from a fuse data storage circuit and first repair data received through a transmission circuit, based on a selection signal;
a second selection circuit configured to selectively output one of second fuse data received from the fuse data storage circuit and second repair data received through the transmission circuit, based on the selection signal;
a first channel region configured to receive the first fuse data from the first selection circuit during a boot-up operation and receive the first repair data from the first selection circuit for a repair operation; and
a second channel region configured to receive the second fuse data from the second selection circuit during the boot-up operation and receive the second repair data from the second selection circuit for the repair operation.

17. The memory device of claim 16, wherein the first selection circuit is configured to:
output the first fuse data during the boot-up operation, and
output the first repair data during the repair operation.

18. The memory device of claim 16, wherein the second selection circuit is configured to:
output the second fuse data during the boot-up operation, and
output the second repair data during the repair operation.

19. The memory device of claim 16,
wherein the first channel region comprises a first repeater configured to receive the first fuse data from a first direction, amplify the first fuse data, and output the amplified first fuse data in a second direction different from the first direction; and
wherein the first repeater is configured to receive the first repair data from the first direction, amplify the first repair data, and output the amplified first repair data in the second direction.

20. The memory device of claim 19, wherein the second direction is opposite to the first direction.

21. The memory device of claim 16,
wherein the second channel region comprises a second repeater configured to receive the second fuse data from a first direction, amplify the second fuse data, and output the amplified second fuse data in a second direction different from the first direction; and
wherein the second repeater is configured to receive the second repair data from the first direction, amplify the second repair data, and output the amplified second repair data in the second direction.

22. The memory device of claim 21, wherein the second direction is opposite to the first direction.

23. A memory device comprising a plurality of core dies stacked over a base die,
wherein each of the plurality of core dies comprises:
a first channel region;
a second channel region;
a transmission circuit positioned in a first direction of the first channel region and positioned in a direction opposite to the first direction of the second channel region; and
a fuse data storage circuit positioned in a second direction of the transmission circuit, wherein the second direction is different from both the first direction and the direction opposite to the first direction,
wherein the first channel region comprises a first repeater configured to receive and amplify first fuse data stored in the fuse data storage circuit during a boot-up operation; and
wherein the first repeater is configured to receive and amplify first repair data transmitted from the base die through the transmission circuit.

24. The memory device of claim 23,
wherein the second channel region comprises a second repeater configured to receive and amplify second fuse data stored in the fuse data storage circuit during the boot-up operation; and
wherein the second repeater is configured to receive and amplify second repair data transmitted from the base die through the transmission circuit.

25. A memory device comprising a plurality of core dies stacked over a base die,
wherein each of the plurality of core dies comprises:
a first channel region;
a second channel region;
a transmission circuit positioned in a first direction of the first channel region and positioned in a direction opposite to the first direction of the second channel region; and
a fuse data storage circuit positioned in the first direction of the first channel region, the transmission circuit, and the second channel region,
wherein the first channel region comprises a first repeater configured to receive and amplify first fuse data stored in the fuse data storage circuit during a boot-up operation; and
wherein the first repeater is configured to receive and amplify first repair data transmitted from the base die through the transmission circuit.

26. The memory device of claim 25,
wherein the second channel region comprises a second repeater configured to receive and amplify second fuse data stored in the fuse data storage circuit during the boot-up operation; and
wherein the second repeater is configured to receive and amplify second repair data transmitted from the base die through the transmission circuit.

27. A memory device comprising a plurality of core dies stacked over a base die,
wherein each of the plurality of core dies comprises:
a first channel region;
a second channel region;
a transmission circuit positioned in a first direction of the first channel region and positioned in a direction opposite to the first direction of the second channel region;
a fuse data storage circuit positioned in a second direction of the transmission circuit;
a first selection circuit positioned in the second direction of the second channel region, wherein the second direction is different from both the first direction and the direction opposite to the first direction; and
a second selection circuit positioned in the second direction of the second channel region,
wherein the first selection circuit is configured to selectively output one of first fuse data received from the fuse data storage circuit and first repair data received through the transmission circuit, based on a selection signal; and
wherein the first channel region is configured to receive the first fuse data from the first selection circuit during a boot-up operation and receive the first repair data from the first selection circuit for a repair operation.

28. The memory device of claim 27, wherein a distance between the fuse data storage circuit and the first channel region is the same as a distance between the fuse data storage circuit and the second channel region.

29. The memory device of claim 28, wherein a distance between the fuse data storage circuit and the first selection circuit is the same as a distance between the fuse data storage circuit and the second selection circuit.

30. The memory device of claim 27,
wherein the second selection circuit is configured to selectively output one of second fuse data received from the fuse data storage circuit and second repair data received through the transmission circuit, based on the selection signal; and
wherein the second channel region is configured to receive the second fuse data from the second selection circuit during the boot-up operation and receive the second repair data from the second selection circuit for the repair operation.
